(19) United States
(12) Patent Application Publication
(10) Pub. No.: US 2024/0254653 A1
(43) Pub. Date: Aug. 1, 2024

(54) CELL ARCHITECTURAL STRUCTURES FOR ENHANCED THERMAL MANAGEMENT IN EPITAXIAL GROWTH PROCESSING CHAMBER

(71) Applicant: Applied Materials, Inc., Santa Clara, CA (US)

(72) Inventors: Amir H. TAVAKOLI, San Jose, CA (US); Ala MORADIAN, Sunnyvale, CA (US); Shawn Thanhson LE, San Jose, CA (US)

(21) Appl. No.: 18/417,016

(22) Filed: Jan. 19, 2024

Related U.S. Application Data
(60) Provisional application No. 63/441,364, filed on Jan. 26, 2023.

(51) Int. Cl. C30B 25/10; C30B 25/08

(52) U.S. Cl. CPC C30B 25/10; C30B 25/08

(57) ABSTRACT

An epitaxial growth processing chamber has a component that has a macrocell support structure. The macrocell support structure has interconnecting physical supports that define fluidly-connected pores. A component configured for use in an epitaxial growth processing chamber has a macrocell support structure with interconnecting physical supports defining fluidly-connected pores. The component may be one or more of a lower liner, an upper liner, a baseplate, an exhaust cap, an injection ring, and an injection cap. The interconnecting physical supports may comprise a material such as a metal, a ceramic or glass material, a polymeric material, and combinations thereof. The component may have a free-standing configuration, a plate-supported configuration, a sandwich configuration, a surface sealed configuration, and a solid polymer-filled configuration.

### CROSS-REFERENCE TO RELATED APPLICATIONS

This application claims the benefit of U.S. Provisional Patent Application Ser. No. 63/441,364, filed on Jan. 26, 2023, the entirety of which is herein incorporated by reference.

### BACKGROUND

### Field

Embodiments described herein generally relate to equipment used in the semiconductor manufacturing, and more particularly, to a substrate processing system with enhanced thermal management.

### Description of the Related Art

Semiconductor substrates are processed for a wide variety of applications, including the fabrication of integrated devices and micro-sized devices. During fabrication, various parameters may affect the functionality of small-sized features formed on the substrate. For example, the temperature uniformity of the substrate or the temperature(s) of processing chamber component(s) can affect the chamber production yield.

In an epitaxial growth processing chamber, which may be utilized to form integrated circuits on a substrate, a set of quartz liners disposed between the substrate edges and the chamber wall provides some measure of thermal shielding for other process chamber components. However, improved temperature control is needed as semiconductor processing advances.

### SUMMARY

An epitaxial growth processing chamber has a component that has a macrocell support structure. The macrocell support structure has interconnecting physical supports that define fluidly-connected pores. The one or more component may be a lower liner, an upper liner, a baseplate, an exhaust cap, an injection ring, an injection cap, or combinations thereof. The interconnecting supports may be comprised of a material that is selected from a metal, a ceramic or glass material, a polymeric material, and combinations thereof. The macrocell support structure may have a porosity in a range of from about 60% to about 99% of the volume of the macrocell support structure. The pores of the macrocell support structure may have an average pore size in a range of from about 1 to about 5000 microns. The macrocell support structure have a permeability in a range of from about 20% to about 100% of the pores of the macrocell support structure. The component having a macrocell support structure may be in a free-standing configuration, a plate-supported configuration, a sandwich configuration, a surface-sealed configuration, and a solid polymer-filled configuration. The component in any configuration may be a unitary component. The component in the plate-supported configuration may include a support plate comprising a similar material to that of than the interconnecting physical supports. The component in the sandwich configuration may include a first plate and a second plate, where each plate comprises a similar material to that of the interconnecting physical supports. The component in the sandwich configuration may be in a configuration where the first plate and the second plate each comprises a different material than the other. The component in the surface sealed configuration may include an encasing surface comprising a different material than the interconnecting physical supports. The component in the surface sealed configuration may further comprises a fluid within the macrocell support structure.

A component configured for use in an epitaxial growth processing chamber has a macrocell support structure with interconnecting physical supports defining fluidly-connected pores. The component may be one or more of a lower liner, an upper liner, a baseplate, an exhaust cap, an injection ring, and an injection cap. The interconnecting physical supports may comprise a material such as a metal, a ceramic or glass material, a polymeric material, and combinations thereof. The macrocell support structure of the component may have a porosity in a range of from about 60% to about 99% of the volume of the macrocell support structure. The pores of the macrocell support structure for the component have an average pore size in a range of from about 1 to about 5000 microns. The macrocell support structure of the component may have a permeability in a range of from about 20% to about 100% of the pores. A component may have a free-standing macrocell support structure configuration, a plate-supported configuration, a sandwich configuration, a surface sealed configuration, or a solid polymer-filled configuration.

### BRIEF DESCRIPTION OF THE DRAWINGS

So that the manner in which the recited features of the present disclosure may be understood in detail, a more particular description of the disclosure may be had by reference to one or more embodiments, some of which are illustrated in the appended drawings. It is to be noted, however, that the appended drawings illustrate only one or more of the several embodiments; therefore, the one or more embodiments provided in the Drawings are not to be considered limiting of the broadest interpretation of the detailed scope. Other effective embodiments as may be described in the Detailed Description may be considered part of the envisioned detailed scope.

FIG. 1 is a schematic side cross-sectional view of an epitaxial growth processing chamber, according to one or more embodiments.

FIGS. 2A-F illustrate cross-sectional representations of portions of macrocell support structures for one or more components for use with an epitaxial growth processing chamber, according to one or more embodiments.

FIGS. 3A and 3B provide top and side views, respectively, of a component comprising a macrocell support structure configured for use with an epitaxial growth processing chamber, according to one or more embodiments.

FIG. 3C provides a free-standing macrocell support structure configuration for the component of FIG. 3A, according to one or more embodiments.

FIG. 3D provides a surface-sealed macrocell support structure configuration for the component of FIG. 3Aer, according to one or more embodiments.

FIGS. 4A and 4B provide side and perspective views, respectively, of a component comprising a microcell support structure configured for use with an epitaxial growth processing chamber, according to one or more embodiments.

FIG. 4C provides a free-standing macrocell support structure configuration for the component of FIG. 4A, according to one or more embodiments.

FIG. 4D provides a surface-sealed macrocell support structure configuration for the component of FIG. 4, according to one or more embodiments.

FIG. 5A-1 provides a top-down view of a non-embodiment component for use with a processing chamber for general discussion purposes. FIG. 5A-2 provides a reveal view along view line CC of the non-embodiment component for use with a processing chamber provided for in FIG. 5A-1 for general discussion purposes.

FIGS. 5B-1, 5C-1, and 5D-1 provide top-down views of a component comprising an macrocell support structure for use with an epitaxial growth processing chamber, according to one or more embodiments. FIGS. 5B-2, 5C-2, and 5D-2 provide a reveal view along view line CC′, CC″, and CC″ of the components comprising an macrocell support structure for use with an epitaxial growth processing chamber provided for in FIGS. 5B-1, 5C-1, and 5D-1, respectively, according to one or more embodiments.

FIG. 6A-1 provides a top-down view of a non-embodiment component for use with a processing chamber for general discussion purposes. FIG. 6A-2 provides a reveal view along view line EE of the non-embodiment component for use with a processing chamber provided in FIG. 6A-1 for general discussion purposes.

FIGS. 6B-2, 6C-2, and 6D-2 each provide a reveal view along view line EE of the components comprising macrocell support structure for use with an epitaxial growth processing chamber provided for in FIG. 6A-1, according to one or more embodiments.

FIG. 7A provides a perspective view of several components comprising a microcell support structure configured for use with an epitaxial growth processing chamber, according to one or more embodiments.

FIGS. 7B, 7C, and 7D each provide a reveal view along view line FF of the components comprising macrocell support structure for use with an epitaxial growth processing chamber provided for in FIG. 7A, according to one or more embodiments.

In this disclosure, the terms “top”, “bottom”, “side”, “above”, “below”, “up”, “down”, “upward”, “downward”, “horizontal”, “vertical”, and the like do not refer to absolute directions. Instead, these terms refer to directions relative to a nonspecific plane of reference. This non-specific plane of reference may be vertical, horizontal, or other angular orientation.

To facilitate understanding and better appreciation for the described scope, in some instances either identical or associated reference numerals have been used (where possible) to designate identical or similar elements, respectively, that are common in the figures. One of skill in the art may appreciate that elements and features of one embodiment may be beneficially incorporated in one or more other embodiments without further recitation.

### DETAILED DESCRIPTION

In the following disclosure, reference may be made to one or more embodiments. However, one of skill in the art does appreciate that the disclosure is not limited to specifically described embodiments. Rather, any combination of features and elements, whether related to different embodiments or not, is contemplated to implement and practice the one or more embodiments provided by the disclosure. Furthermore, although the one or more embodiments presented in the disclosure may achieve advantages over other possible solutions, the prior art (if existing), and combinations thereof, whether or not a particular advantage is achieved by a given embodiment is not limited by this disclosure. The aspects, features, embodiments, and advantages provided are merely illustrative. These are not considered elements or limitations of the appended claims except where explicitly recited in one or more of the Claims. Likewise, one of skill in the art should not construe a reference to “the disclosure” as a generalization of any disclosed subject matter.

The present disclosure relates to alternative compositions of various components of the epitaxial growth processing chamber that may provide improved thermal insulation and shielding over prior-known materials and configurations. It is well appreciated that in the micro-processor fabrication industry that there are issues of substrate temperature non-uniformity that may appear during the use of epitaxial growth processing chambers. Non-uniform and out-of-specification temperature(s) at the end of a substrate may cause a reduction in product yield due to defective materials. Insufficient thermal shielding in portions of the processing vessel, especially along portions of the vessel in contact with the relatively cooler external environment, may result in excessive electrical consumption to heat and maintain the temperature in the interior of the processing chamber. Not controlling heat dissipation—either permitting too rapid of heat loss/gain or too slow of heat loss/gain—may strain components through thermal shock or thermal degradation, reducing their operative lifespan. Increased maintenance of the processing chambers also reduces overall product yield due to downtime.

Using components including a macrocell support structure, which is a network of interconnecting physical supports forming pores is an approach not yet appreciated in the art for controlled shielding of thermal energy. Using metal, ceramic, glass, or polymer interconnecting physical supports along with potentially supporting plates or enclosures of gases, liquids, or even different solids may provide not only the capability to absorb electromagnetic (EM) energy in the form of light and heat but also retain such energy and slowly re-emit the energy in the form of heated gases such that thermal shock does not occur. As well, configurations may be made such that the interconnecting physical supports and protective layers may reflect EM energy to conserve and redistribute energy not absorbed by the substrate being processed, saving energy.

Metal, ceramic, glass, or polymer macrocell structures have permeability and a significant overall pore volume fraction. Integrating or replacing certain components of the process chamber with such architectures is believed to influence not only the energy management of the process chamber but also the effectiveness of the process itself through a combination of energy reflecting and shielding and heat dissipation.

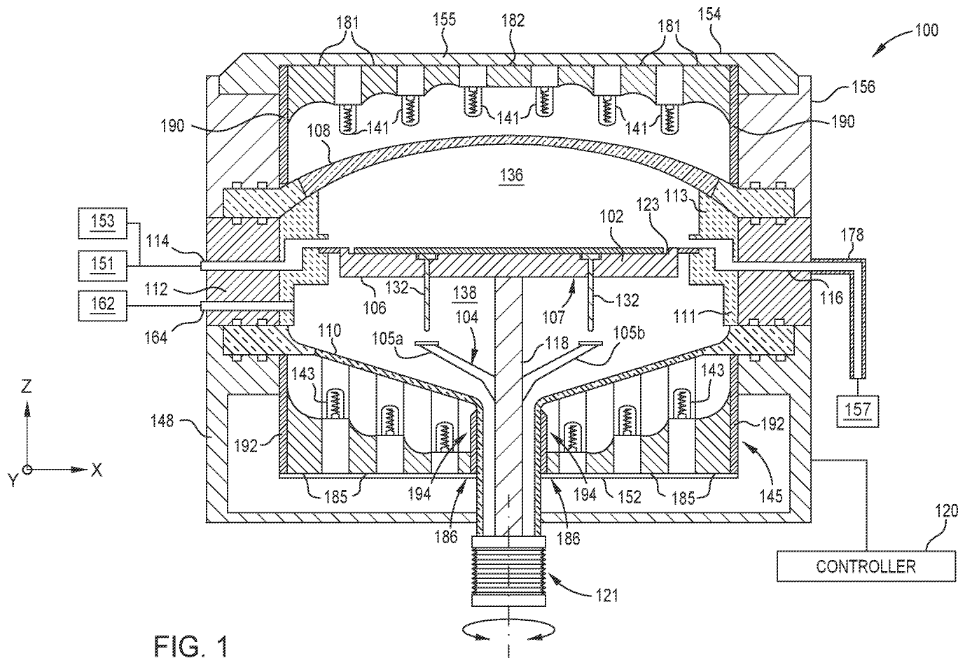

FIG. 1 is a schematic side cross-sectional view of an epitaxial growth processing chamber 100. The processing chamber 100 is an epitaxial deposition chamber. Such a processing chamber 100 may be utilized to grow an epitaxial film on a substrate 102. The processing chamber 100 may create a cross-flow of precursors across a top surface 150 of the substrate 102.

The processing chamber 100 may include an upper body 156, a lower body 148 disposed below the upper body 156, a baseplate 112 disposed between the upper body 156 and the lower body 148. The upper body 156, the baseplate 112, and the lower body 148 may form a chamber body. Positioned within the chamber body may be a substrate support 106, an upper window 108, such as an upper dome, a lower window 110, such as a lower dome, a plurality of upper lamps 141, and a plurality of lower lamps 143. The lower window 110 also extends downwards through which shaft 118 extends. The baseplate 112 may couple the upper body 156 and the lower body 148 together, such as shown in FIG. 1, through upper window 108 and lower window 110, respectively, to from a gas-tight sealed volume. A controller 120 may be in communication with the processing chamber 100. The controller may be used to control processes and methods, such as the operations of the epitaxial growth processing chamber.

The substrate support 106 may be positioned between the upper window 108 and the lower window 110. The substrate support 106 may include a support face 123 that supports the substrate 102.

The plurality of upper lamps 141 may be disposed between the upper window and a lid 154. The plurality of upper lamps 141 may form a portion of the upper lamp module 155. The lid 154 may include a plurality of sensors (not shown) for measuring the temperature within the processing chamber 100. The upper window 108 may be an upper dome and formed of an energy transmissive material, such as quartz.

The plurality of upper lamps 141 may form a series of concentric rings, such as two sets, three sets, or more sets of rings of upper lamps 141 as part of the upper lamp module 155. Upper lamp module 155 in FIG. 1 may also include several ring-shaped reflectors with concave reflective surfaces 181 positioned between a pair of two adjacent concentric rings of upper lamps 141 or between a concentric ring of upper lamps 141 and the upper body 156. Upper lamp module 155 may also include a reflector with a flat reflective surface 182 positioned between a pair of two adjacent concentric rings or within a ring of upper lamps 141. Each reflective surface 181, 182 may have a surface configured to reflect EM radiation downwards onto a specific area of the substrate 102.

In the process chamber 100, upper lamp module 155 also may have a heat shield 190 positioned around the outside circumference of the outer-most concentric rings of upper lamps 141. The heat shield 190 may have a coating to reflect EM radiation back into the interior of the upper lamp module 155. The heat shield 190 may also assist in insulating the processing chamber 100, protecting the upper lamp module 155 from rapid temperature changes. Insulation such as provided by heat shield 190 should provide for gradual temperature increases and declines to prevent thermal shock to the components of the upper lamp module 155, which may extend the operative life span of the components of the upper lamp module 155. The upper lamp module 155 may have more than one heat shield 190, including a heat shield positioned between each concentric rings of lamp modules. In such instances, each heat shield 190 may be configured to protect the lower portions of the lamp modules in a similar manner.

The plurality of lower lamps 143 may be positioned between the lower window 110 and a floor 152 of the processing chamber 100. The plurality of lower lamps 143 form a portion of a lower lamp module 145. The lower window 110 may be formed of an energy transmissive material, such as quartz.

The plurality of lower lamps 143 may form a series of concentric rings, such as two sets, three sets, or more sets of rings of lower lamps 143 as part of the lower lamp module 145. Lower lamp module 145 in FIG. 1 may also include several reflectors with concave reflecting surfaces 185 positioned between a pair of two adjacent concentric rings of upper lamps 141 or between a concentric ring of lower lamps 143 and the lower body 148. Lower lamp module 145 may also include a reflector with a flat reflective surface 186 positioned between a pair of two adjacent concentric rings or within a ring of lower lamps 143. Each reflective surface 185, 186 may have a surface configured to reflect EM radiation upward back into the processing chamber 100.

In processing chamber 100, lower lamp module 145 may also have a heat shield 192 positioned around the outside circumference of the outer-most concentric rings of lower lamps 143. The heat shield 192 in some instances may have an exterior coating to reflect EM radiation back into the interior of the lower lamp module 145. The heat shield 192 assists in insulating the processing chamber 100, which protects the lower lamp module 145 from rapid temperature changes. The lower lamp module may have more than one heat shield, similar to the upper lamp module.

Lower lamp module 145 in processing chamber 100 also shows a cone reflector 194. Cone reflector 194 is positioned around the outside circumference of the shaft 118 proximate to the inner-most ring of lower lamps 143. The cone reflector 194 is configured on an exterior-facing surface a reflective surface to reflect any EM radiation from the inner-most lower lamps 143 outward and upward. The cone reflector 194 may also be configured to be an insulator to prevent rapid heat transitions on that portion of the lower window 110 upon operation of the lower lamps 143, which may prevent formation of a severe thermal gradient moving up the shaft 118 and the lowest-most portion of the lower window 110 upon activation/deactivation of the lower lamps 143. The cone reflector 194 also may prevent cyclic thermal stresses from forming in the material of the lower window 110, which is often made of quartz, by slowing the heating and cooling processes.

A process volume 136 and a purge volume 138 may be defined between the upper window 108 and the lower window 110. The process volume 136 and the purge volume 138 may be a portion of a greater internal volume defined at least partially by the upper window 108, the lower window 110, and the one or more liners. The processing chamber 100 includes a lower liner 111 aligned at least partially below the substrate support 106 and an upper liner 113 aligned at least partially above the substrate support 106. The upper liner 113 and lower liner 111 are shown in FIG. 1 positioned along an inner surface of the baseplate 112 to protect the baseplate 112 from the reactive gases introduced and used during deposition operations, cleaning operations, or both.

The internal volume may further include the substrate support 106. The substrate support 106 may include an upper surface onto which the substrate 102 is positioned. The substrate support 106 may be coupled or connected to a shaft 118. The shaft 118 may be coupled or connected to a motion assembly 121. The motion assembly 121 may include one or more of actuators, adjustment devices, or both, that provide movement, adjustment, or both, for the shaft 118, the substrate support 106, or both, within the processing volume 136.

The substrate support 106 may be configured to define one or more lift pin holes 107. The lift pin holes 107 may be configured to accommodate a lift pin 132 for lifting of the substrate 102 from the substrate support 106 either before or after a deposition process is performed. A stop 104 includes a plurality of arms 105a, 105b that each include a lift pin stop onto which the lift pins 132 may rest when lowered.

The baseplate 112 may include one or more of gas inlets 114, a one or more of purge gas inlets 164, and one or more gas exhaust outlets 116. The one or more of gas inlets 114 and the one or more of purge gas inlets 164 may be positioned on the opposite side of the baseplate 112 from the one or more gas exhaust outlets 116. The gas inlet(s) 114 and the purge gas inlet(s) 164 may each be positioned such that a gas may flow parallel to the top surface 150 of a substrate 102 positioned within the process volume 136. The gas inlet(s) 114 may be fluidly connected to one or more process gas sources 151 and one or more cleaning gas sources 153. The purge gas inlet(s) 164 may be fluidly connected to one or more purge gas sources 162. The one or more gas exhaust outlets 116 may be fluidly connected to an exhaust pump 157.

One or more process gases supplied using the one or more process gas sources 151 may include one or more reactive gases, such as silicon (Si), phosphorus (P), and germanium (Ge), one or more carrier gases, such as one or more of nitrogen (N₂) and hydrogen (H₂), and combinations thereof. One or more purge gases supplied using the one or more purge gas sources 162 may include one or more inert gases, such as argon (Ar), helium (He), nitrogen (N₂). One or more cleaning gases supplied using the one or more cleaning gas sources 153 may include one or more of hydrogen (H) and chlorine (CI). The one or more process gases may include silicon phosphide (SiP), phospine (PH₃), and combinations thereof. The one or more cleaning gases may include hydrochloric acid (HCl). The epitaxial growth processing chamber is configured to process such materials internally without significant degradation and in the presence of human operators observing normal operation.

The one or more gas exhaust outlets 116 may be further coupled or connected to an exhaust cap 178. The exhaust cap 178 may fluidly connect the one or more gas exhaust outlets 116 to the exhaust pump 157. The exhaust cap 178 may assist be utilized on controlling the deposition of a layer on the substrate 102 by regulating pressure differential within the epitaxial growth processing chamber, which may impact the gas flow across the surface of the substrate and therefore the deposition rate. The exhaust cap 178 may be positioned on an opposite side of the processing chamber 100 relative to the baseplate 112.

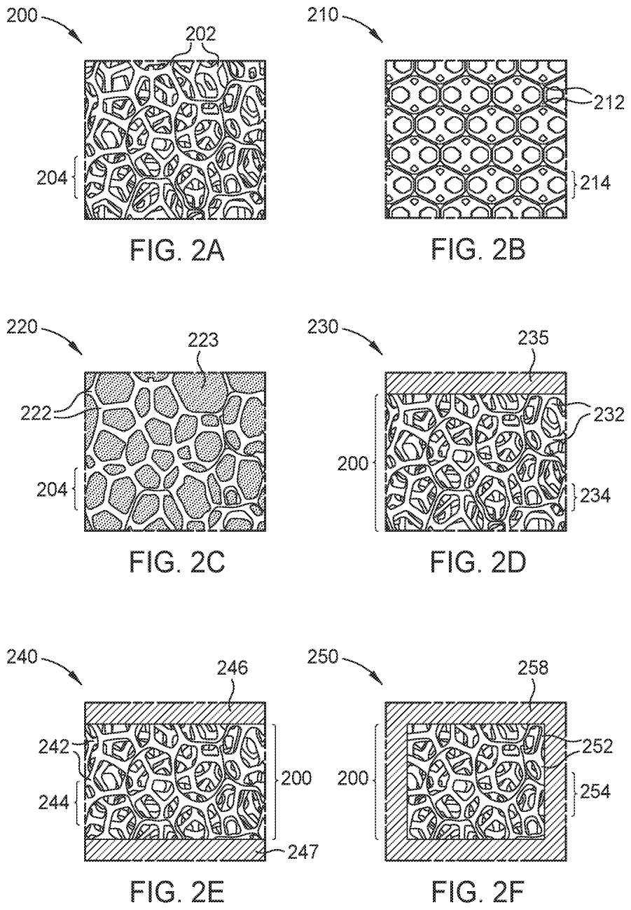

In one or more embodiments, an epitaxial growth processing chamber is configured with one or more components including macrocell support structures. In one or more embodiments, a component configured for use in an epitaxial growth processing chamber includes a macrocell support structures. Non-limiting examples of such macrocell support structures are provided in FIGS. 2A-F. FIGS. 2A-F display several cross-sectional representations of portions of macrocell support structures useful in one or more components for use with an epitaxial growth processing chamber.

FIG. 2A displays a cross-sectional representation of a portion of macrocell support structure. A macrocell support structure, such as the structure represented in rectangle 200, has interconnecting physical supports 202 that form a three-dimensional (3D) interconnected network; a lattice or a matrix. The spaces or voids in between the interconnecting physical supports 202 define a plurality of voids or pores 204. In many instances for a macrocell support structure, the pores 204 are in fluid communication with one another, that is, the pores are “open”, which will be described further, such that a fluid, such as a gas or a liquid, may flow in any axial direction through the macrocell support structure shown in rectangle 200.

In one or more embodiments, the configuration of the interconnecting physical supports for the macrocell support structure may be reticulated, that is, random or varied, such as represented by the configuration of the interconnecting physical supports 202 for rectangle 200 in FIG. 2A. FIG. 2B displays a second cross-sectional representation of a portion of a second macrocell support structure. In one or more embodiments, the configuration of the interconnecting physical supports 212 may be in a regular or repeating structure, such as represented by rectangle 210 in FIG. 2B. As seen in 210, both the interconnecting physical supports 212 and pores 214 are uniform, repeating, and regularly spread structures. Such a configuration may provide predictability not only for fluid flow but also heat transfer through the macrocell support structure given its uniform arrangement.

The interconnecting physical supports provide a much greater degree of internal strength and resistance to deformation. The macrocell support structure is weight-bearing and keeps form under elevated thermal conditions and stress from weight and pressure. In one or more embodiments, useful macrocell support structures do not thermally degrade or decompose in a temperature range of from about 0° C. to about 1000° C., such as from about 0 to about 100, 200, 300, 400, 500, 600, 700, 800, 900, and 1000° C., including all range combinations and end points inclusive. To “thermally degrade or decompose” means that a material either undergoes a chemical reaction where chemical bonds are either cleaved between bonded pairs of atoms or a chemical reaction, such as oxidation, occurs that converts the heated material into another material, such that where the result of either occurrence throughout the material results in a loss of physical integrity on a macro scale. In one or more embodiments, useful macrocell support structures are configured to be exposed to pressures in a range of from 1×10⁻⁵ atmospheres to about 1.5 atmospheres, such as 0.00001, 0.0001, 0.001, 0.01, and 0.1 atmospheres to about 0.2, 0.3., 0.5, 0.7, 0.8, 0.9, 1.0, 1.1, 1.2, 1.3, 1.4, and 1.5 atmospheres of pressure, including all range combinations and end points inclusive. A pressure value less than atmospheric pressure is considered a “partial vacuum”.

In one or more embodiments, the interconnecting physical supports of the macrocell support structure comprise a metal, such as aluminum, aluminum alloys, iron, iron alloys, nickel, nickel alloys, copper, copper alloys, or combinations thereof. An example of a useful aluminum alloy is 6061 aluminum. An example of a useful iron alloy is stainless steel, such as 316L stainless steel. An example of a useful nickel alloy is Hastelloy. An example of a useful copper alloy is brass.

In one or more embodiments, the interconnecting physical supports of the macrocell support structure comprise a ceramic or glass material, such as reticulated vitreous/glassy carbon (RVC); silicon carbide coated RVC; silicon carbide; silicon nitride; quartz, such as black quartz; carbon fiber products, such as carbon fiber fabrics; or combinations thereof.

In one or more embodiments, the interconnecting physical supports of the macrocell support structure comprise a polymer material. In one or more embodiments, the polymer material is a thermoset polymer. In one or more embodiments, the polymer is a thermoplastic material. A polymer that is useful in this type of process is one that has a glass transition temperature (Tg) that is greater than about 350° C. In one or more embodiments, the polymer may be a thermoset polymer, poly(ethyl ether ketone) (PEEK), a polyimide, or combinations thereof.

A feature of a macrocell support structure is the size of its pores versus the overall volume of the material. In one or more embodiments, the macrocell support structure has a void volume or porosity percentage in a range of from about 60% to about 99% by volume, such as 60, 70, 75, 80, 85, and 90 to about 91, 92, 93, 94, 95, 96, 97, 98, and 99% by volume, including all range combinations and end points inclusive.

In one or more embodiments, the average void or pore within the macrocell support structure has a width in a range of from about 1 to about 5000 microns, such as 1, 5, 10, 20, 30, 40, 50, 60, 70, 80, 90, 100, 150, 200, 250, 300, 400, 500, 600, 700, 800, 900, 1000, 1250, 1500, 1750, and 2000 to 2250, 2500, 2750, 3000, 3250, 3500, 3750, 4000, 4250, 4500, 4750, and 5000 microns in width, including all range combinations and end points inclusive. “Width” represents a measurable distance between two interconnecting physical supports on opposing sides of a defined void or pore volume, similar to opposing corners for a diagonal for a cube or a diameter for a sphere.

The combination of the configuration of the macrocell support structures and the number of pores not only reduces the weight of the components compared to traditional process chamber components but also provides significant thermal flexibility and stress distribution throughout the component. By being able to distribute stress throughout the structure and to convey thermal energy throughout the component, including into the fluid contained within and traversing the pores, the component including the macrocell support structure is less likely to fail due to a thermal stress caused by a thermal gradients that form during the heating and cooling process, unlike a more solid part that may generate repeated internal stresses due to the gradient traversing through the solid structure and causing differences in expansion rate, eventually resulting in the formation of stress-based faults or cracks.

Another feature of macrocell support structure is permeability. One may appreciate that the permeability of the macrocell support structure permits fluid to flow among the interconnecting physical supports to transfer energy. The permeability of the macrocell support structure is reflected in the amount of pores that are not fluidly isolated from other pores; that is, the fluid connectivity between pores. The permeability through the interconnecting physical supports defining the pore structures allows gases, such as nitrogen, argon, helium, other noble gases, and other gases that are generally inert to the material, to either naturally flow through or be forced through the macrocell support structure, such as using a pressurized fluid flow or a mass driver. Although one or more of the pores in the macrocell support structure may be interconnected, some of the pores within the overall macrocell support structure may not contribute to fluid communication through the overall macrocell support structure. Such pores are fluidly isolated and act as insulative cavities, whether as one pore or more, and do not contribute to the permeability of the macrocell support structure.

In one or more embodiments, the macrocell support structure has a permeability of greater than about 20% to 100% permeability, such as greater than about 20, 30, 40, 50, 55, 60, 65, 70, 75, 80, 85, and 90 to about 91, 92, 93, 94, 95, 96, 97, 98, 99, 99.9, 99.99, 99.999, about 100, and 100% permeability, including all range combinations and end points inclusive.

Although in some instances not all of the pores or voids may be in fluid communication with other pores, that is, some pores are closed, fluidly isolated, or “dead”, this is not necessarily a flaw or defect in the configuration of the microcell structure. A lack of permeability for a minority portion of the macrocell support structure may allow the vaporous fluids previously described to be remain trapped within the support structure. These dead pores may then act as limited “heat sinks”: absorbing energy conveyed through the interconnecting physical supports and permitting additional absorption of heat, retaining such heat until the local interconnecting physical supports have cooled sufficiently, and then releasing such heat back into the cooling interconnecting physical supports. This permits a degree of slower heating and cooling of the component with some “closed” macrocells versus an “open” macrocell support structure form not having such isolated voids or pores. Slower heating and cooling of components is believed to increases the longevity of the component including such a macrocell support structure but also the other components around the structure by slowing their change in temperature too. Another potential advantage is that in one or more embodiment configurations the closed voids may be positioned proximate to or in contact with an interior portion of a surface, such as an interior surface of a support panel, a sandwich panel, or a portion of an enclosing surface. Such sealed pores may not only act as a temperature buffer as previously described but also provide additional mechanical coupling or connectivity at the point of coupling or connecting between the surfaces and the interconnecting physical supports by increasing the amount of material coupling or contacting the surface at the point of interface.

Components that are configured to be useful with the epitaxial growth processing chamber that are at least in part comprised of the macrocell support structure may have one or more physical configurations. FIGS. 2A and 2B, which were previously presented, display cross-sectional representations of free-standing macrocell support structures. In one or more embodiment, a component is configured such that the component is only comprised of the macrocell support structure, that is, it is a free-standing macrocell support structure. In such an instance, the component only includes the macrocell support structure. The component consists or consist essentially of the macrocell support structure, which is defined by interconnecting physical supports. Rectangles 200 and 210 both represent a portion of a component that does not have any external cladding, mounting, shielding, surface, or protection. All of the external surfaces of the component are exposed; both the pores and the interconnecting physical supports are fluidly accessible through the exterior surfaces of the component. Unless a surface is sealed with a film or layer, a fluid may traverse through the macrocell support structure mostly unimpeded (except for interconnecting physical supports and potentially a closed pore) in any axial direction.

FIG. 2C displays a cross-sectional representation of a polymer-filled free-standing macrocell support structure. In one or more embodiments, a component is configured such that the component has a macrocell support structure with pores filled with a second solid material. In such a configuration, the second solid material, such as second solid material 223 within pores 224 of rectangle 220, is different than the material of the interconnecting physical supports 222 of the macrocell support structure. In FIG. 2C, rectangle 220 is similar in structure to rectangle 200 and 210 of FIGS. 2A and 2B; however, the interior pore structure 224 is completely filled with a second solid material. In one or more embodiments, the second solid material may be a polymer, such as a thermoset polymer, PEEK, a polyimide, or combinations thereof.

The second solid material of the “solid polymer-filled” configuration should not expand or contract with temperature change at a significantly different rate than the interconnecting physical supports to prevent physically stressing the macrocell support structure as well as degrading the overall composite structure. As well, the second solid material should not melt, liquefy, degrade, or decompose under normal or even foreseeable extreme operating conditions of the component or the epitaxial growth processing chamber. The second solid material may soften at an elevated temperature, such as a thermoset polymer may be known to do as its absorbs energy and its bonds stretch within the polymer matrix; however, the second solid material should not otherwise lose physical integrity of form or swell other than an expected expansion and contraction at most due to temperature cycling and exposure to the vapor of the process, if so exposed.

FIG. 2D displays a cross-sectional representation of a plate-supported macrocell support structure. In one or more embodiments, a component is in a plate-supported configuration. Rectangle 230 represents a portion of a component that is “plate supported”. Support plate 235 in one or more embodiments is coupled to the interconnecting physical supports 232; in one or more embodiments, the support plate is connected to the interconnecting physical supports 232. A coupling may be through an intermediary coupling layer (not shown), such as an adhesive layer, that binds an interior surface of the support plate 235 to exterior contact points along an exterior surface of the macrocell support structure. A connection may be made directly through known connective techniques, such as, but not limited to, welding, brazing, diffusion bonding, and mechanical affixation, such as through bolting or clamping.

In one or more embodiments, the parts of a plate-supported configuration component comprise different materials. For example, the interconnecting physical supports of the macrocell support structure may be made of a ceramic material or a first metal and the support plate may be made of a second metal. In one or more embodiments where the plate-supported component includes different materials, the coefficients of expansion for the different parts of the plate-supported component are within ±10% of one another Such a composite material may have an advantage of providing reflectivity from the support surface, insulation properties from the macrocell support structure, and cost benefits for substituting more expensive materials and bonding techniques; however, care is advised in that the different parts materials should have similar coefficients of expansion/contraction within the operating temperature range of the component to avoid damaging the manner of coupling or connecting the parts of the plate-supported component. In one or more embodiments, the parts of a plate-supported configuration component comprise the same material.

In instances where the parts of a plate-supported configuration component may comprise the same material, in one or more embodiments the plate-supported component is a unitary component. That is, there are no seams, separations, gaps, or breaks in between the interconnecting physical supports along the exterior surface of the macrocell support structure where the support plate couples and the support plate that necessitates coupling or connection; the component is a singular, unified object. Such a component may be fabricated using known manufacturing process, such as, but not limited to, additive manufacturing, such as three-dimensional (3D) printing; subtractive manufacturing; compression molding; injection molding; and casting.

In one or more embodiments, the external-facing surface of the support plate may be modified surface. In some instances, the external-facing surface may be modified, such as mechanically or chemically, to directly alter its characteristics, such as by scoring, matting, etching, polishing, oxidation, and acid or alkali treatment. In such direct treatments, the properties of the material including the support plate itself may be enhanced to perform certain functions, such as bonding with another material or reflecting electromagnetic (EM) radiation. In some other instances, the external-facing surface may be modified by coupling or connecting an external layer onto the external-facing surface. For example, a reflective film or a mirrored surface may be adhered or cladded to the exterior surface to reflect EM radiation. Other such modifications to the exterior-facing surface of the support-plate are appreciated and envisioned.

FIG. 2E displays a cross-sectional representation of a sandwich macrocell support structure. In one or more embodiments, a component is in a sandwich configuration. Rectangle 240 represents a portion of a component that is in a sandwich configuration having a first plate 246 and a second plate 247 positioned on different surfaces of the interconnecting physical supports 242. As shown in FIG. 2E, the plates 246, 247 may be positioned opposing one another, but it is envisioned that for alternative configurations, such as having a triangular exterior surface, that the two surfaces, such as plates 246, 247 may not be directly opposing one another (for example, adjacent). Such a configuration is similar to the plate-supported configuration except there are two or more plates on opposing or different surfaces rather than a single support plate. In one or more embodiments, the first and second plates are coupled or connected to the interconnecting physical supports of the macrocell support structure.

In one or more embodiments, the parts of a sandwich component comprise different materials, e.g., the first plate 246 includes a first material and the second plate 247 includes a second material. In one or more embodiments where parts of the sandwich component comprise different materials, e.g., the first material and the second material are different, the coefficients of expansion for the different parts of the sandwich component are within +10% of one another. In one or more embodiments, the parts of a sandwich component comprise the same material, e.g., the first material and the second material are the same. In instances where the parts of a sandwich component may comprise the same material, e.g., the first plate, the second plate, and the interconnecting physical supports include the same material, in one or more embodiments the sandwich configured component is a unitary component. In one or more embodiments, one or both of the external-facing surfaces of either or both the first or second plate may be a modified surface. Examples previously given included polishing, etching, and mounting a reflective layer upon the externally-facing surface. In such a sandwich configured component, the first plate may have an external-facing surface that is scored to promote adhesion and the second play may have an external-facing surface that finely polished to reflect EM radiation.

FIG. 2F displays a cross-sectional representation of a surface sealed macrocell support structure. In one or more embodiments, a component is in a surface sealed configuration. Rectangle 250 represents a portion of a component that is in a surface sealed configuration. An encasing surface 258 surrounds all external sides of the interconnecting physical supports of the macrocell support structure. The encasing surface 258 may include a material different from the material of the interconnecting physical supports. Alternatively, the encasing surface 258 may include a material that is the same as the material of the interconnecting physical supports. Such surface sealed does not permit a fluid, such as a gas, liquid, or supercritical fluid, to traverse into or out of the macrocell support structure; rather, the structure and any fluids contained within the pores are sealed fluidly within the structure. Based upon the permeability, the fluid may move about within the structure throughout the component, redistributing heat by convection of mass. In one or more embodiments, the surface sealing is coupled or connected to the interconnecting physical supports of the macrocell support structure.

In one or more embodiments, the parts of a surface sealed component comprise different materials. In one or more embodiments where parts of the surface sealed component comprise different materials, the coefficients of expansion for the different parts of the surface sealed component are within +10% of one another. In one or more embodiments, the parts of a surface sealed component comprise the same material. In instances where the parts of a surface sealed component may comprise the same material, in one or more embodiments the surface sealed configuration component is a unitary component. In one or more embodiments, one, some or all of the external-facing surface of the enclosing surface may be a modified surface.

When there is a surface sealed component, the pores of the macrocell support structure are filled with a gas, such as nitrogen, argon, helium, other noble gases, and other gases generally non-reactive with the component, and combinations thereof. The gas within the surface sealed configuration is either about at atmospheric pressure or less than atmospheric pressure at room temperature. This permits the pressure of the gas trapped within the surface sealed component to rise upon exposure to the heat of the process. In one or more embodiments, the pressure within a surface sealed component at room temperature is in a range of from about 1×10⁻⁵ atmospheres to about 1.0 atmosphere, such as 0.00001, 0.0001, 0.001, 0.01, and 0.1 atmospheres to about 0.2, 0.3., 0.5, 0.7, 0.8, 0.9, and 1.0 atmosphere, including all range combinations and end points inclusive.

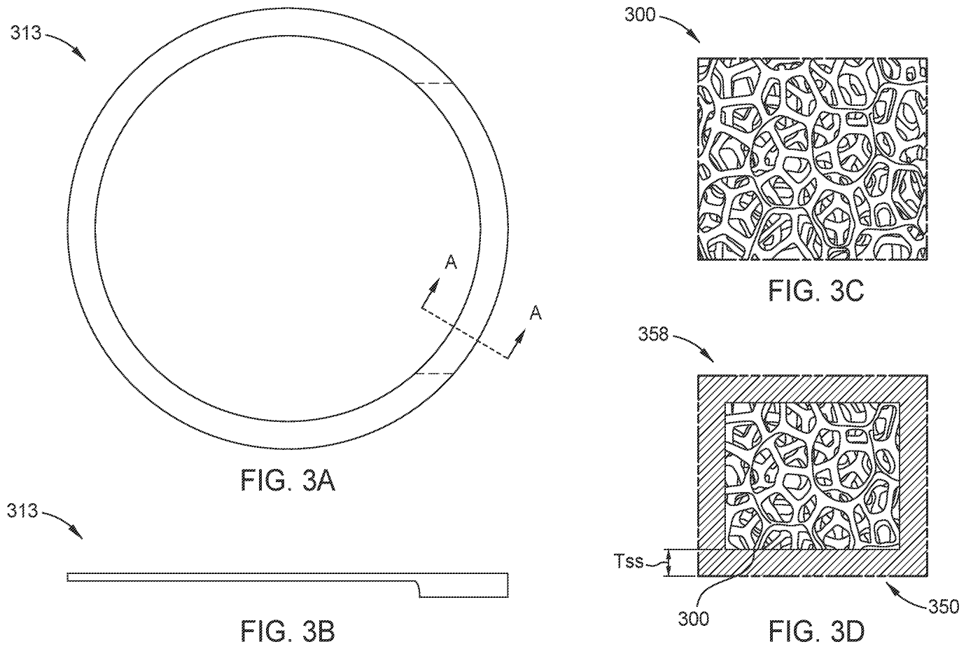

FIGS. 3A and 3B provide top and side views, respectively, of a component including a macrocell support structure configured for use with an epitaxial growth processing chamber. As provided for in FIGS. 3A and 3B, in one or more embodiments a component with a macrocell support structure configured for use with an epitaxial growth processing chamber includes an upper liner 313. Upper liner 313 is similar to the upper liner 113 described for processing chamber 100 provided in FIG. 1. Although an embodiment upper liner 313 is shown in FIGS. 3A and 3B, one of ordinary skill in the art appreciates that an embodiment upper liner also includes those with different overall physical dimensions, such as, but not limited to, thickness, width, circumference, and diameter that are suitable for proper operation in what is appreciated as an epitaxial growth processing chamber.

As viewed along view lines AA of FIG. 3A, there may be one or more useful macrocell support structure configurations for use in with an epitaxial grown processing chamber. In one or more embodiments, an upper liner is configured such that the upper liner is comprised of the free-standing macrocell support structure; in one or more embodiments, the upper liner is configured such that the upper liner consists essentially of or consist of the free-standing macrocell support structure. FIG. 3C provides a free-standing macrocell support structure configuration for the upper liner. The upper liner may be in the free-standing macrocell support structure configuration, such as displayed in FIG. 3C as rectangle 300, which is similar to rectangle 200 of FIG. 2A, although other macrocell support structures are available for use. In one or more embodiments, the interconnecting physical supports of the macrocell support structure of the upper liner is comprised of a ceramic or glass material. Such materials are completely inert to the epitaxy process environment.

In one or more embodiments, an upper liner is configured in a surface sealed configuration. FIG. 3D provides a surface-sealed macrocell support structure configuration for the upper liner. Rectangle 350 is similar to rectangle 250, except in the example shown in FIG. 3D there is a non-reticular interconnecting physical support shown within the surface sealed macrocell support structure of the upper liner. As previously described, the interconnecting physical supports for any embodiment component may be either in the reticular or regular configuration. In one or more embodiment, the surface sealed macrocell support structure for the upper liner is comprised of a ceramic or glass material. A gas is contained within the pores and voids of the surface sealed macrocell support structure for the upper liner.

The surface of the surface sealed macrocell support structure has a determinable amount of material, which may vary from implementation to implementation. For example, the thickness of the sealed surface, such as Tss as shown in FIG. 3D, of the sealing surface, such as 358, may be characterized as a relative percentage of areas of a cross-section of the component. This may be useful to do so when the thicknesses of various surfaces of the component are not equal or equivalent on all sides but there is an overall consistency of surface protection throughout the component. In one or more embodiments, the sealing surface has a cross-sectional area in a range of from about 0.001% to about 25% of a cross-sectional area of the upper liner, such as from about 0.001, 0.01, 0.1, 1, 2, 3, 5, 10, 15, 20, and 25%, including all range combinations and end points inclusive. It is appreciated by one of ordinary skill in the art that this cross-sectional area value may change depending upon the viewing position and therefore may vary from one value to another in the given range. In another instances, such as where the sealing surface thickness is more uniform throughout the component, the sealing surface thickness may simply be directly measured for an absolute thickness value. In one or more embodiments, the surface seal thickness for the upper liner is in a range of from about 0.01 mm (millimeters) to about 3 mm, such as from about 0.01, 0.02, 0.03, 0.04, 0.05, 0.1, 0.2, 0.3, 0.5, 0.7, and 0.9 to about 1.0, 1.5, 2.0, 2.5, and 3.0 mm, including all range combinations and end points inclusive.

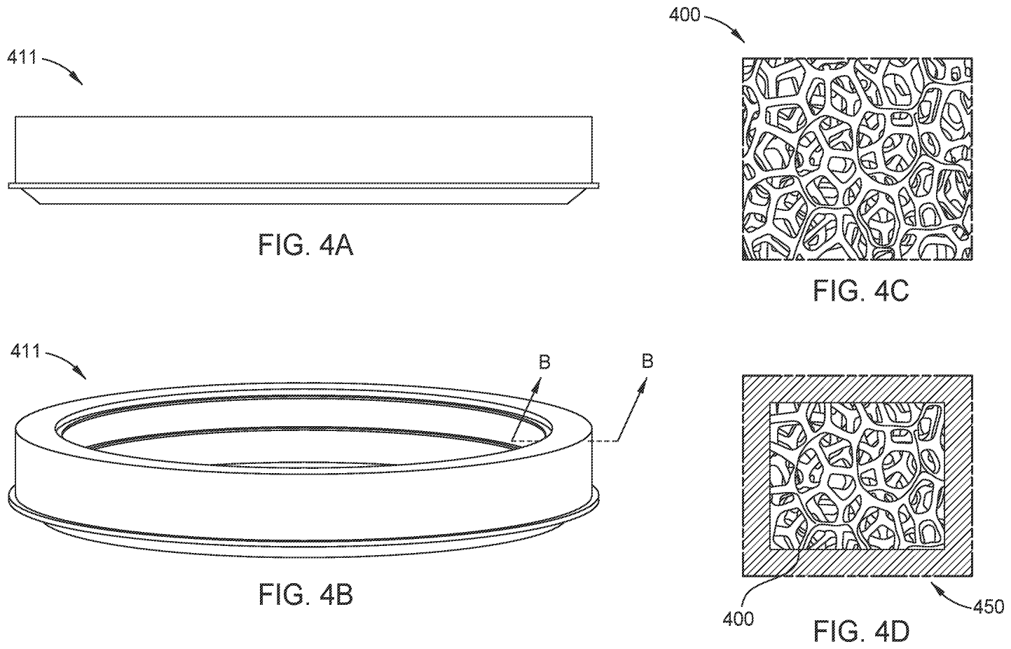

FIGS. 4A and 4B provide side and perspective views, respectively, of a component including a microcell support structure configured for use with an epitaxial growth processing chamber. As provided for in FIGS. 4A and 4B, in one or more embodiments a component including a microcell support structure for use with an epitaxial growth processing chamber may include a lower liner 411. Lower liner 111 is similar to the lower liner 111 described for processing chamber 100 as provided in FIG. 1. Although an embodiment lower liner 411 is shown in FIGS. 4A and 4B, one of ordinary skill in the art appreciates that an embodiment lower liner also includes those with similar or different overall physical dimensions, such as, but not limited to, thickness, width, circumference, and diameter, that are suitable for proper operation in what is appreciated as an epitaxial growth processing chamber.

As viewed along view lines BB of FIG. 4B, there may be one or more useful macrocell support structure configurations for use in with an epitaxial grown processing chamber. In one or more embodiments, a lower liner is configured such that the lower liner is comprised of the free-standing macrocell support structure; in one or more embodiments, the lower liner is configured such that the lower liner consists essentially of or consist of the free-standing macrocell support structure. FIG. 4C provides a free-standing macrocell support structure configuration for the lower liner. The lower liner may be in the free-standing macrocell support structure configuration, such as displayed in FIG. 4C as rectangle 400, which is similar to rectangle 200 of FIG. 2A, although other macrocell support structures are available for use. In one or more embodiments, the interconnecting physical supports of the macrocell support structure of the lower liner is comprised of a ceramic or glass material.

In one or more embodiments, a lower liner is configured in a surface sealed configuration. FIG. 4D provides a surface-sealed macrocell support structure configuration for the lower liner. Rectangle 450 is similar to rectangle 250, except in the example shown in FIG. 4D there is a non-reticular interconnecting physical support shown within the surface sealed macrocell support structure of the lower liner. In one or more embodiment, the surface sealed macrocell support structure for the lower liner is comprised of a ceramic or glass material. A gas is contained within the pores and voids of the surface sealed macrocell support structure for the lower liner. In one or more embodiments, the surface seal has a cross-sectional area in a range of from about 0.001% to about 25% of a cross-sectional area of the lower liner, such as from about 0.001, 0.01, 0.1, 1, 2, 3, 5, 10, 15, 20, and 25%, including all range combinations and end points inclusive. It is appreciated by one of ordinary skill in the art that this cross-sectional area value may change depending upon the viewing position and therefore may vary from one value to another in the given range. In one or more embodiments, the sealing surface thickness for the lower liner is in a range of from about 0.01 mm (millimeters) to about 3 mm, such as from about 0.01, 0.02, 0.03, 0.04, 0.05, 0.1, 0.2, 0.3, 0.5, 0.7, and 0.9 to about 1.0, 1.5, 2.0, 2.5, and 3.0 mm, including all range combinations and end points inclusive.

The surface sealed macrocell support structure for the lower liner in one or more embodiments has a surface sealing structure that includes a ceramic or glass material. The surface sealed macrocell support structure for the lower liner in one or more embodiments has interconnecting physical supports of the macrocell support structure that comprise a ceramic or glass material. In one or more embodiments, the composition of the ceramic or glass surface sealing structure and the interconnecting physical supports that comprise the same material.

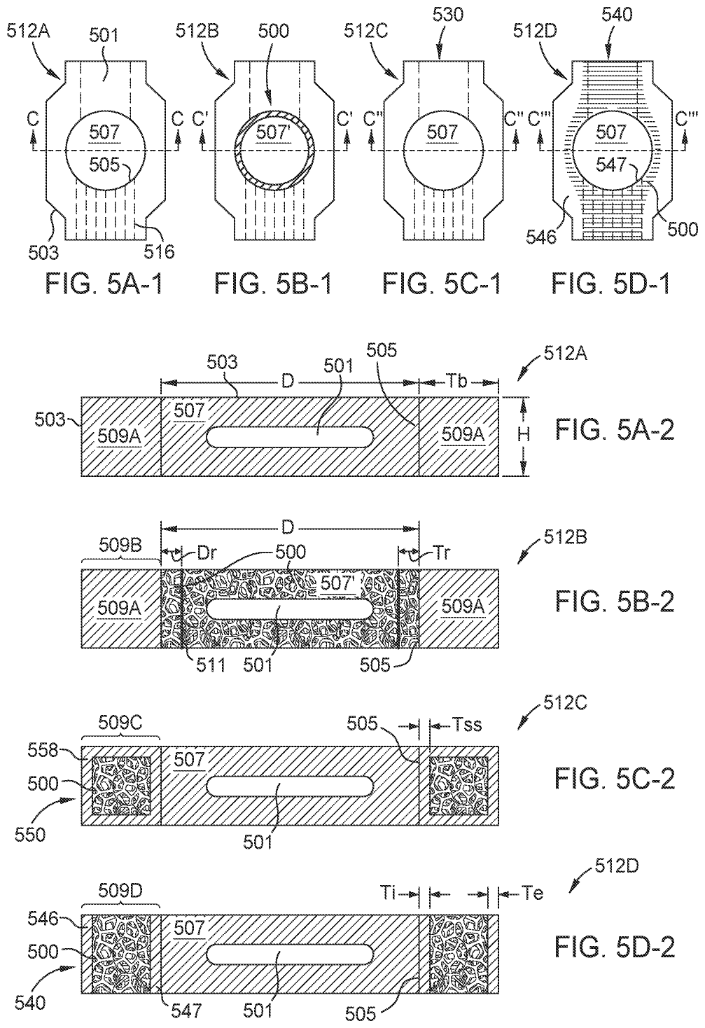

FIG. 5A-1 provides a top-down view of a non-embodiment component for use with a processing chamber for general discussion purposes. Epitaxial baseplate 512A may be of similar configuration to the baseplate 112 of processing chamber 100 in FIG. 1. FIG. 5A-2 provides a reveal view along view line CC of the non-embodiment component for use with a processing chamber provided for in FIG. 5A-1 for general discussion purposes. FIG. 5A-2 reveal view is directed towards the side of the baseplate 512A defining the substrate slot 501 and away from the one or more gas exhaust outlets 516. In FIGS. 5A-1 and 5A-2, baseplate 512A is shown with several features, including substrate slot 501, an exterior surface 503, and an interior surface 505 that define the physical bounds of the baseplate 512A itself. Interior surface 505 also defines a cylindrical volume 507 within baseplate 512A that is at least a portion of the process volume, previously described as process volume 136 in FIG. 1 of a processing chamber 100. The cylindrical volume 507 and the interior surface 505 both have a diameter “D” between opposing points. For baseplate 512A, there is also a uniform height “H” throughout. Using FIG. 5A-2, both the edges of the interior surface (arrow for 509) at the view line as well as the interior surface of the interior structure 509 around the remaining semi-circular surface, which also includes a view through substrate slot 501, may be observed. At the point where reveal view CC occurs, an interior structure 509 of the baseplate 512A is revealed—in this instances a fully solid material—having a thickness of “Tb” that represents the thickness of the baseplate at that view line. Although a non-embodiment baseplate 512A is shown in FIGS. 5A-1 and 5A-2 for discussion purposes, one of ordinary skill in the art appreciates that both non-embodiment and embodiment baseplates also includes those with similar or different overall physical dimensions, such as, but not limited to, interior process volume circumference and diameter; baseplate thickness, width, and length; substrate slot dimensions and configurations, and number, position, and types of gas exhaust outlets, that are suitable for proper operation in what is appreciated as an epitaxial growth processing chamber.

FIG. 5B-1 provides a top-down view of a component including a macrocell support structure for use with an epitaxial growth processing chamber. FIG. 5B-2 provides a reveal view along view line CC′ of the components including an macrocell support structure for use with an epitaxial growth processing chamber provided for in FIG. 5B-1. In one or more embodiments, which may be combined with other embodiments, a free-standing macrocell support structure is coupled or connected to an interior surface of the baseplate, such as in a ring or an annular configuration of free-standing macrocell support 500, which can be viewed from top-down in FIG. 5A-1. The ring or annular configuration of free-standing macrocell support is shown integrated onto an existing structure, such as structure epitaxial baseplate 512B without removing or replacing any of the interior structure 509B, that is, the interior structure 509A of epitaxial baseplate 512A and interior structure 509B of epitaxial baseplate 512B are similar or the same in configuration. The baseplates 512A and 512B have the same baseplate thickness (Tb) at the same viewing points (along view lines CC and CC′, respectively). The ring or annual configuration of the macrocell support structure 500 is coupled to or connected to the interior surface 505 of the baseplate 512B using any known or appreciated coupling or connecting technique, including frictional, adhesive, physical, such as bolts, retaining screws, or key slots on or through interior surface 505. In one or more embodiments, the ring or an annular configuration of free-standing macrocell support is configured to frictionally couple with the interior surface of the baseplate. The outer surface of the ring or annular configuration of the macrocell support structure 500 in some instances has about the same diameter (D) as the interior surface 505 of the baseplate 512A.

Although not shown in detail, the ring or annular configuration of free-standing macrocell support structure is configured for operations to occur within the interior of the baseplate. For example, the ring or annular configuration would define an extension of void that the baseplate 512B defines as the substrate slot 501 such that a substrate may ingress and egress the process chamber. As can be observed in FIG. 5A-2, substrate slot 501 is visible through the ring or annular configuration of free-standing macrocell support 500. As well, the ring or annular configuration would also define extensions of the one or more flow conduits that the baseplate 512B defines as the one or more gas exhaust outlets 516, as may be observed in the top-down representation give in FIG. 5A-1.

The ring or annular configuration 500 has an annular thickness (Tr) in a range of from about 0.1% to about 25% of the diameter of the interior surface of the baseplate (D), such as from about 0.1, 0.2, 0.3, 0.5, 1.0, 2.0, 3.0, 5.0, 7.0, and 9.0 to about 10.0, 11.0, 12.0, 13.0, 14.0, 15.0, 20.0, and 25.0% of the diameter of the interior surface of the baseplate (D). The annular thickness (Tr) of the ring or an annular configuration of free-standing macrocell support for the baseplate therefore does have an impact upon the “working” cylindrical volume 507′ comparatively. Cylindrical volume 507′ is less than cylindrical volume 507 when present, albeit the void volume of the ring or an annular configuration of free-standing macrocell support would also act as part of the processing volume, so in relative perspective the gas volume is not decreased but the physical volume that the substrate could occupy would be decreased by a more significant volume. The reduction in volume for cylindrical volume 507′ comparatively is by a degree of D minus Tr, which is defined as “Dr” in FIG. 5B-2. Dr is defined as the diameter formed by opposing points along the interior surface 511 of the ring or annular configuration of the macrocell support structure 500, as may be seen in FIG. 5B-2.

The free-standing macrocell support structure for the epitaxial baseplate in one or more embodiments has interconnecting physical supports comprised of a ceramic or glass material.

FIGS. 5C-1 provides top-down view of a component including a macrocell support structure for use with an epitaxial growth processing chamber, according to one or more embodiments. FIG. 5C-2 provides a reveal view along view line CC″ of the components including a surface sealed macrocell support structure for use with an epitaxial growth processing chamber provided for in FIG. 5C-1. In other embodiments, a baseplate is configured such that is in a surface sealed configuration. As represented in FIG. 5C-2 along view lines CC″ surface sealed macrocell support structure 550 shows that there is a volume of interior structure 509C having a thickness Tb that is comprised of an macrocell support structure that is similar to surface sealed macrocell support structure shown in rectangle 250 of FIG. 2F. One of ordinary skill in the art appreciates that other macrocell support structures are available to the baseplate.

As seen in FIG. 5C-2, the entirety of macrocell support structure 500 is surface sealed by a sealing surface 558 in this instance. The surface sealing structure has a thickness (Tss). In one or more embodiments, the surface sealing structure includes a cross-sectional area of in a range of from about 0.001% to about 25% of a cross-sectional area of the baseplate, such as from about 0.001, 0.01, 0.1, 1, 2, 3, 5, 10, 15, 20, and 25%, including all range combinations and end points inclusive. One of ordinary skill in the art appreciates that the cross-sectional area value may change depending upon the viewing position and therefore may vary in value from one value to another value within the range based upon position measured.

The surface sealed macrocell support structure for the epitaxial baseplate in one or more embodiments has a surface sealing structure that includes a ceramic or glass material. The surface sealed macrocell support structure for the epitaxial baseplate in one or more embodiments has interconnecting physical supports of the macrocell support structure that comprise a ceramic or glass material.

5D-1 provides top-down views of a component including a macrocell support structure for use with an epitaxial growth processing chamber, according to one or more embodiments. 5D-2 provides a reveal view along view line CC″″ of the components including an macrocell support structure for use with an epitaxial growth processing chamber provided for in 5D-1. In one or more embodiments, a baseplate is configured such that is in a sandwich configuration. As represented in FIG. 5D-2 along view lines CC′″, sandwich macrocell support structure 540 shows that there is a volume of interior structure 509D having a thickness Tb that is comprised of an macrocell support structure that is similar to sandwich macrocell support structure shown in rectangle 240 of FIG. 2E. As viewed from above, the sandwich macrocell support structure 540 is visible, especially the region of macrocell support structure 500 in between the first plate 546 and the second plate 547. Although not literally shaped as “plates” in this instance, which may evoke an image of a flat surface, one of ordinary skill in the art appreciates that the lexicography is in keeping with the example of a sandwich macrocell support structure configuration previously described and associated with rectangle 240 in FIG. 2E, and is still applicable here and in other embodiments.

As seen in FIG. 5D-2, the entirety of macrocell support structure 500 is contained in between first plate 546, which acts as the exterior-facing plate of baseplate 512D, and second plate 547, which acts as the interior-facing plate of baseplate 512D. The first plate has a thickness (Te); the second plate has a thickness (Ti). In one or more embodiments, the thickness of the first plate (Te) is in a range of from about 0.05 to about 5 mm, such as from 0.05, 0.07, 0.1, 0.2, 0.3, 0.5, 0.7, 0.9, and 1.0 to about 1.5, 2.0, 2.5, 3.0, 3.5, 4.0, 4.5, and 5.0 millimeters (mm), including all range combinations and end points inclusive. In one or more embodiments, the thickness of the second plate (Ti) is in a range of from about 0.05 to about 5 mm, such as from 0.05, 0.07, 0.1, 0.2, 0.3, 0.5, 0.7, 0.9, and 1.0 to about 1.5, 2.0, 2.5, 3.0, 3.5, 4.0, 4.5, and 5.0 millimeters (mm), including all range combinations and end points inclusive. In one or more embodiments, the first and the second plates have the same or similar thickness; in another embodiment, the first plate has a greater thickness than the second plate; in another embodiment, the first plate has a lesser thickness than the second plate. There may be differences in thicknesses between the two plates for a variety of reasons, including, but not limited to, overall mechanical strength of the baseplate and safety and containment of the process fluid during operation. The thickness of the macrocell support structure would therefore be determined as the baseplate thickness (Tb) minus the sum of the two plate thicknesses (Ti+Te). One of ordinary skill in the art appreciates that the first and the second plate thicknesses may change depending upon the viewing position and therefore may vary in value from one value to another value within the range based upon position measured.

In such a sandwich configuration, the interconnecting physical supports of the macrocell support structure may be comprised of a metal. In one or more embodiments, first plate and the second plate are made of a metal. In one or more embodiments, which may be combined with other embodiments, the first plate and the second plate are both made of the same material as the interconnecting physical supports. However, it is also contemplated that the first plate and the second plate may either or both be made of a different metal material than the interconnecting physical supports.

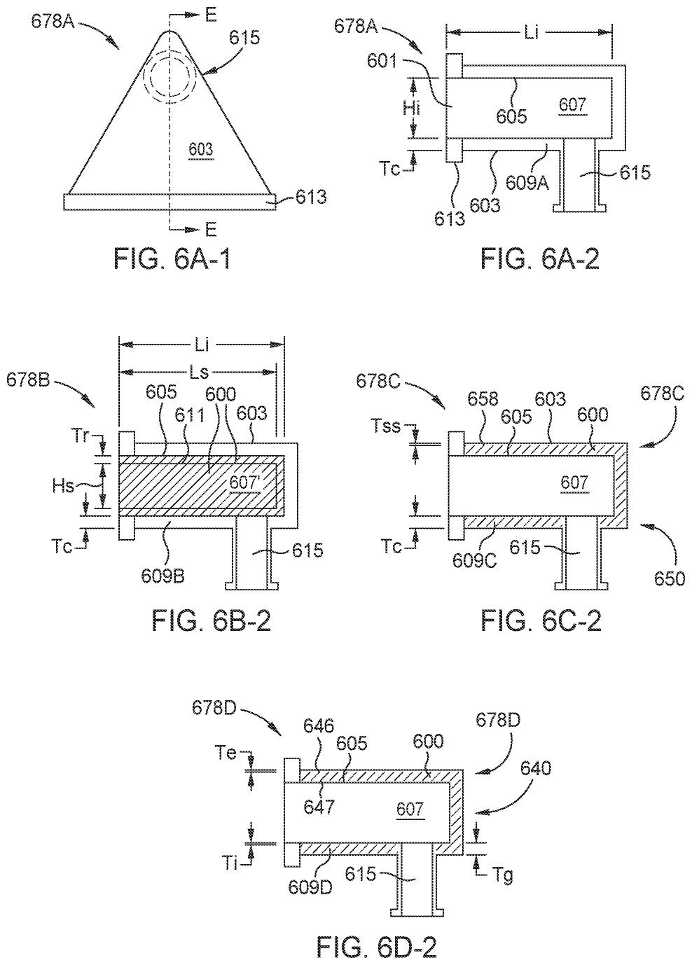

FIG. 6A-1 provides a top-down view of a non-embodiment component for use with a processing chamber for general discussion purposes. Epitaxial exhaust cap 678A may be of similar configuration to exhaust cap 178 of processing chamber 100 in FIG. 1. FIG. 6A-2 provides a reveal view along view line EE of the non-embodiment component for use with a processing chamber provided in FIG. 6A-1 for general discussion purposes. The FIG. 6A-2 reveal view is directed towards what would be a vertical side of the exhaust cap 678A when in position as part of a processing chamber. In the reveal figure, entry port 601 is defined by coupling flange 613 and is usually in fluid communication with a process chamber, such as process chamber 100 when coupled or connected. Entry port 601 is fluidly accessible to interior 607, which is mostly defined by interior surface 605. Exterior surface 603 is visible in both FIGS. 6A-1 and 6A-2 as the top of the exhaust cap 678A. 609A is the interior structure of exhaust cap 678A. Outlet port 615 is fluidly accessible to interior 607 and permits gases that move through 678A to be discharged from the exhaust cap 678A. Several dimensions are useful for describing aspects of potential embodiment exhaust caps. “Hi” is defined as the height between opposing points along the interior surface 605 of the lower and upper portions of the exhaust cap 678A. “Li” is defined as the length or depth between the entry port 601 and an opposing side of the exhaust cap 678A, such as along view line EE. “Tc” is the thickness of the surface of the exhaust cap 678A, such as the thickness of interior structure 609A. Although an non-embodiment exhaust cap 678A is shown in FIGS. 6A-1 and 6A-2, one of ordinary skill in the art appreciates that an embodiment exhaust cap also includes those with different overall physical dimensions, such as, but not limited to, thickness, width, height, volume, outlet port position and diameter, coupling or connectivity means to the baseplate, that are suitable for proper operation in what is appreciated as an epitaxial growth processing chamber.

For the several embodiments of exhaust cap, FIG. 6A-1 represents the exterior top-down view of all of the embodiment macrocell support structure structures to be described. FIG. 6B-2 provides a second reveal view along view line EE of the components including a macrocell support structure for use with an epitaxial growth processing chamber provided for in FIG. 6A-1. For FIGS. 6B-2, 6C-2, and 6D-2, hatching is utilized to represent the presence and location of macrocell support structure for the purposes of viewing clarity. In one or more embodiments, which may be combined with other embodiments, a free-standing macrocell support structure is coupled or connected to an interior surface of the exhaust cap, such as sheets of free-standing macrocell support 600. The free-standing macrocell support is shown integrated onto an existing structure, such as structure epitaxial exhaust cap 678B, without removing or replacing any of the interior structure 609B, that is, the interior structure 609A of epitaxial exhaust cap 678A and interior structure 609B of epitaxial exhaust cap 678B are similar or the same in configuration. The exhaust caps 678A and 678B have the same exhaust cap thickness (Tc) at the same viewing points (along view lines EE). The free-standing macrocell support structure 600 is coupled to or connected to the interior surface 605 of the exhaust cap 678B using any known or appreciated coupling or connecting technique, as previously described. In one or more embodiments, the free-standing macrocell support structure is configured to frictionally couple with the interior surface of the exhaust cap. The outer surface of the free-standing macrocell support structure 600 in some instances has about the same shape and dimensionality, including interior height (Hi) and interior length (Li), as the interior surface 605 of the exhaust cap 678B.

Although not shown in detail, the free-standing macrocell support structure is configured for operations to occur within the interior of the exhaust cap. For example, the free-standing macrocell support structure defines define an extension of void that the exhaust cap 678B defines as the exhaust port 615 such that gases may egress from the exhaust cap. Other configurations may be provided as needed to support operations.

The free-standing macrocell support structure 600 has a thickness (Tr) in a range of from about 0.1% to about 25% of the height of the interior surface (Hs) of the exhaust cap, such as from about 0.1, 0.2, 0.3, 0.5, 1.0, 2.0, 3.0, 5.0, 7.0, and 9.0 to about 10.0, 11.0, 12.0, 13.0, 14.0, 15.0, 20.0, and 25.0% of the height of the interior surface of the exhaust cap. The thickness (Tr) of the free-standing macrocell support structure does have an impact upon the “working” interior 607′ comparatively in a similar manner as previously described with cylindrical volume 507′ of FIGS. 5B-1 and 5B-2: the gas volume would be reduced by the amount of volume the interconnecting physical supports occupy, but the physical volume is more restricted to the height Hs, which in addition to two thicknesses Tr is the original height Hi of exhaust cap 678A. The same may also be characterized for the reduction in physical length between original length Li and revised length Ls for interior 607′, which the difference should be Tr. Given that only vapor is passing through the exhaust cap 678B, the loss in useful volume is minimal.

The free-standing macrocell support structure for the exhaust cap in one or more embodiments has interconnecting physical supports comprised of a ceramic or glass material.

FIG. 6C-2 provides a third reveal view along view line EE of the components including a surface sealed macrocell support structure for use with an epitaxial growth processing chamber provided for in FIG. 6A-1. In other embodiments, an exhaust cap 678C is configured such that is in a surface sealed configuration. As represented in FIG. 6C-2 along view lines EE, surface sealed macrocell support structure 650 shows that there is a volume of interior structure 609C having a thickness Tc that is comprised of an macrocell support structure that is similar to surface sealed macrocell support structure shown in rectangle 250 of FIG. 2F. One of ordinary skill in the art appreciates that other macrocell support structures are available to the exhaust cap.

As seen in FIG. 6C-2, the entirety of macrocell support structure 600 is surface sealed by a sealing surface 658 in this instance. The surface sealing structure has a thickness (Tss). In one or more embodiments, the surface sealing structure includes a cross-sectional area of in a range of from about 0.01% to about 25% of a cross-sectional area of the exhaust cap, such as from about 0.001, 0.1, 1, 2, 3, 5, 10, 15, 20, and 25%, including all range combinations and end points inclusive. One of ordinary skill in the art appreciates that the cross-sectional area value may change depending upon the viewing position and therefore may vary in value from one value to another value within the range based upon position measured.

The surface sealed macrocell support structure for the epitaxial exhaust cap in one or more embodiments has a surface sealing structure that includes a ceramic or glass material. The surface sealed macrocell support structure for the epitaxial exhaust cap in one or more embodiments has interconnecting physical supports of the macrocell support structure that comprise a ceramic or glass material.

FIG. 6D-2 provides a reveal view along view line EE of the components including an macrocell support structure for use with an epitaxial growth processing chamber provided for in 6A-1. In one or more embodiments, an exhaust cap is configured such that is in a sandwich configuration. In other embodiments, an exhaust cap is configured such that is in a sandwich configuration. As represented in FIG. 6D-2 along view lines EE, sandwich macrocell support structure 640 shows that there is a volume of interior structure 609D having a thickness Tc that is comprised of an macrocell support structure that is similar to sandwich macrocell support structure shown in rectangle 240 of FIG. 2E. The region of macrocell support structure 600 in between the first plate 646 and the second plate 647.

As seen in FIG. 6D-2, the entirety of macrocell support structure 600 is contained in between first plate 646, which acts as the exterior-facing plate of exhaust cap 678D, and second plate 547, which acts as the interior-facing plate of exhaust cap 678D. The first plate has a thickness (Te); the second plate has a thickness (Ti). In one or more embodiments, the thickness of the first plate (Te) is in a range of from about 0.05 to about 5 mm, such as from 0.05, 0.07, 0.1, 0.2, 0.3, 0.5, 0.7, 0.9, and 1.0 to about 1.5, 2.0, 2.5, 3.0, 3.5, 4.0, 4.5, and 5.0 millimeters (mm), including all range combinations and end points inclusive. In one or more embodiments, the thickness of the second plate (Ti) is in a range of from about 0.05 to about 5 mm, such as from 0.05, 0.07, 0.1, 0.2, 0.3, 0.5, 0.7, 0.9, and 1.0 to about 1.5, 2.0, 2.5, 3.0, 3.5, 4.0, 4.5, and 5.0 millimeters (mm), including all range combinations and end points inclusive. In one or more embodiments, the first and the second plates have the same or similar thickness; in another embodiment, the first plate has a greater thickness than the second plate; in another embodiment, the first plate has a lesser thickness than the second plate. There may be differences in thicknesses between the two plates for a variety of reasons as previously described. The thickness of the macrocell support structure would therefore be determined as the exhaust cap thickness (Tc) minus the sum of the two plate thicknesses (Ti+Te). One of ordinary skill in the art appreciates that the first and the second plate thicknesses may change depending upon the viewing position and therefore may vary in value from one value to another value within the range based upon position measured.

In such a sandwich configuration, the interconnecting physical supports of the macrocell support structure may be comprised of a metal. In one or more embodiments, first plate and the second plate are made of a metal. In one or more embodiments, which may be combined with other embodiments, the first plate and the second plate are both made of the same material as the interconnecting physical supports. However, it is also contemplated that the first plate and the second plate may either or both be made of a different metal material than the interconnecting physical supports.

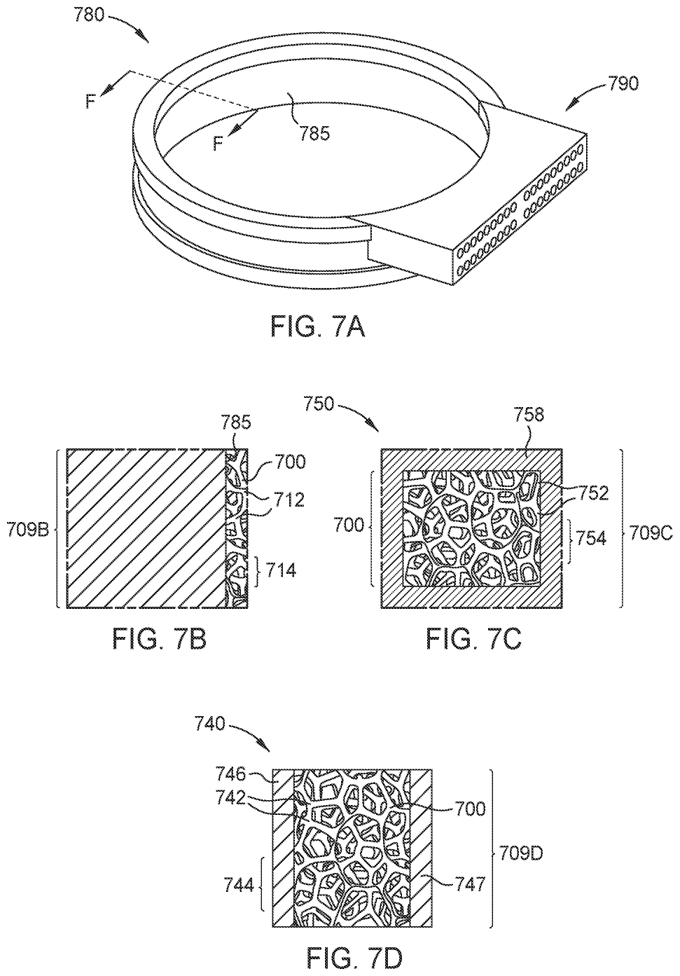

FIG. 7A provides a perspective view of several components including a microcell support structure configured for use with an epitaxial growth processing chamber. As provided for in FIG. 7A, in one or more embodiments a component including a microcell support structure for use with an epitaxial growth processing chamber may include an injection ring, such as injection ring 780. Also provided for in FIG. 7A and shown coupled to injection ring 780, in one or more embodiments a component including a microcell support structure for use with an epitaxial growth processing chamber may include an injection cap, such as injection cap 790. Although an embodiment injection ring 780 and an embodiment injection cap 790 are shown in FIG. 7A, one of ordinary skill in the art appreciates that an embodiment of either the injection cap or the injection ring may have similar or different overall physical dimensions, such as, but not limited to, thickness, width, circumference, number of injection orifices, the manner and means by which injection cap and injection ring couple to one another or if they are a singular piece, and diameter, that are suitable for proper operation in what is appreciated as an epitaxial growth processing chamber.

As viewed along view plane FF of FIG. 7A, there may be one or more macrocell support structure that are useful for configuring an injection ring for use in an epitaxial growth processing chamber. FIG. 7B provides a reveal view along view line FF of the components including a macrocell support structure for use with an epitaxial growth processing chamber provided for in FIG. 7A. In one or more embodiments, which may be combined with other embodiments, a free-standing macrocell support structure is coupled or connected to an interior surface of the injection ring 780, such as in a ring or an annular configuration of free-standing macrocell support 700. As seen in FIG. 7B, none of the interior structure 709B of the injection ring 780 is modified; the ring or annular configuration of the macrocell support structure 700 is similar in configuration to the ring or annular configuration of the macrocell support structure 500 as provided for the baseplate 512B, except that certain configurational differences are accommodated, such as the differences in ports or holes to support the introduction of gases. The ring or annular configuration of free-standing macrocell support is shown integrated onto an existing structure, such as structure epitaxial injection ring 780 without removing or replacing any of the interior structure 709B. The ring or annual configuration of the macrocell support structure 500 is coupled to or connected to the interior surface 785 of the injection ring 780 using any known or appreciated coupling or connecting technique, including frictional, adhesive, physical, such as bolts, retaining screws, or key slots on or through interior surface 785. In one or more embodiments, the ring or an annular configuration of free-standing macrocell support is configured to frictionally couple with the interior surface of the injection ring. The outer surface of the ring or annular configuration of the macrocell support structure 700 in some instances has about the same diameter as the interior surface 785 of the injection ring 780.

Although not shown in detail, the ring or annular configuration of free-standing macrocell support structure is configured for operations to occur within the interior of the injection ring. For example, the ring or annular configuration defines extensions of the one or more flow conduits that the injection cap defines to permit gas flow into the operating area.

The ring or annular configuration has an annular thickness in a range of from about 0.1% to about 25% of the diameter of the interior surface of the injection ring, such as from about 0.1, 0.2, 0.3, 0.5, 1.0, 2.0, 3.0, 5.0, 7.0, and 9.0 to about 10.0, 11.0, 12.0, 13.0, 14.0, 15.0, 20.0, and 25.0% of the diameter of the interior surface of the injection ring.

The free-standing macrocell support structure for the epitaxial injection ring in one or more embodiments has interconnecting physical supports comprised of a ceramic or glass material.

FIG. 7C provides a reveal view along view line EE of the components including a surface sealed macrocell support structure for use with an epitaxial growth processing chamber provided for in FIG. 7A. In other embodiments, an injection ring is configured such that is in a surface sealed configuration. As represented in FIG. 7C along view lines EE, surface sealed macrocell support structure 750 shows that there is a volume of interior structure 709C having a thickness that is comprised of an macrocell support structure that is similar to surface sealed macrocell support structure shown in rectangle 250 of FIG. 2F. One of ordinary skill in the art appreciates that other macrocell support structures are available to the injection ring.

As seen in FIG. 7C, the entirety of macrocell support structure 700 is surface sealed by a sealing surface 758 in this instance. The surface sealing structure has a thickness. In one or more embodiments, the surface sealing structure includes a cross-sectional area of in a range of from about 0.001% to about 25% of a cross-sectional area of the injection ring, such as from about 0.01, 0.1, 1, 2, 3, 5, 10, 15, 20, and 25%, including all range combinations and end points inclusive. One of ordinary skill in the art appreciates that the cross-sectional area value may change depending upon the viewing position and therefore may vary in value from one value to another value within the range based upon position measured.

The surface sealed macrocell support structure for the epitaxial injection ring in one or more embodiments has a surface sealing structure that includes a ceramic or glass material. The surface sealed macrocell support structure for the epitaxial injection ring in one or more embodiments has interconnecting physical supports of the macrocell support structure that comprise a ceramic or glass material.

FIG. 7D provides a reveal view along view line EE of the components including a macrocell support structure for use with an epitaxial growth processing chamber provided for in FIG. 7A. In one or more embodiments, an injection ring is configured such that is in a sandwich configuration. As represented in FIG. 7D along view lines EE, sandwich macrocell support structure 740 shows that there is a volume of interior structure 709D having a thickness that is comprised of an macrocell support structure that is similar to sandwich macrocell support structure shown in rectangle 240 of FIG. 2E. The sandwich macrocell support structure 740 is visible, especially the region of macrocell support structure 700 in between the first plate 746 and the second plate 747.

As seen in FIG. 7D, the entirety of macrocell support structure 700 is contained in between first plate 746, which acts as the exterior-facing side, and second plate 747, which acts as the interior-facing side. The first plate has a thickness and the second plate has a thickness. In one or more embodiments, the thickness of the first plate is in a range of from about 0.05 to about 5 mm, such as from 0.05, 0.07, 0.1, 0.2, 0.3, 0.5, 0.7, 0.9, and 1.0 to about 1.5, 2.0, 2.5, 3.0, 3.5, 4.0, 4.5, and 5.0 millimeters (mm), including all range combinations and end points inclusive. In one or more embodiments, the thickness of the second plate is in a range of from about 0.05 to about 5 mm, such as from 0.05, 0.07, 0.1, 0.2, 0.3, 0.5, 0.7, 0.9, and 1.0 to about 1.5, 2.0, 2.5, 3.0, 3.5, 4.0, 4.5, and 5.0 millimeters (mm), including all range combinations and end points inclusive. In one or more embodiments, the first and the second plates have the same or similar thickness; in another embodiment, the first plate has a greater thickness than the second plate; in another embodiment, the first plate has a lesser thickness than the second plate. There may be differences in thicknesses between the two plates for a variety of reasons, including, but not limited to, overall mechanical strength of the baseplate and safety and containment of the process fluid during operation. The thickness of the macrocell support structure would therefore be determined as the injection ring thickness minus the sum of the two plate thicknesses. One of ordinary skill in the art appreciates that the first and the second plate thicknesses may change depending upon the viewing position and therefore may vary in value from one value to another value within the range based upon position measured.

In such a sandwich configuration, the interconnecting physical supports of the macrocell support structure may be comprised of a metal. In one or more embodiments, first plate and the second plate are made of a metal. In one or more embodiments, which may be combined with other embodiments, the first plate and the second plate are both made of the same material as the interconnecting physical supports. However, it is also contemplated that the first plate and the second plate may either or both be made of a different metal material than the interconnecting physical supports.

Injection cap, such as injection cap 790 of FIG. 7A, has like features and aspects as the previously described injection ring, such as injection ring 780, including embodiment macrocell support structure configurations, compositions, and arrangements. This is to minimize the amount of difference in operation when both the injection ring and the inject cap are coupled together for operation.

While this specification contains many specific implementation details, these should not be construed as limitations on the scope of what can be claimed, but rather as descriptions of features that can be specific to particular implementations. Certain features that are described in this specification in the context of separate implementations can also be implemented, in combination, in a single implementation. Conversely, various features that are described in the context of a single implementation can also be implemented in multiple implementations, separately, or in any suitable sub-combination. Moreover, although previously described features can be described as acting in certain combinations and even initially claimed as such, one or more features from a claimed combination can, in some cases, be excised from the combination, and the claimed combination can be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional) to achieve desirable results. In certain circumstances, multitasking or parallel processing (or a combination of multitasking and parallel processing) can be advantageous and performed as deemed appropriate.

Moreover, the separation or integration of various system modules and components in the previously described implementations should not be understood as requiring such separation or integration in all implementations. It should be understood that the described program components and systems can generally be integrated together in a single software product or packaged into multiple software products.

Accordingly, the previously described example implementations do not define or constrain the present disclosure. Other changes, substitutions, and alterations are also possible without departing from the spirit and scope of the present disclosure.

Furthermore, any claimed implementation is considered to be applicable to at least a computer-implemented method; a non-transitory, computer-readable medium storing computer-readable instructions to perform the computer-implemented method; and a computer system including a computer memory interoperability coupled with a hardware processor configured to perform the computer-implemented method or the instructions stored on the non-transitory, computer-readable medium.

While the various steps in an embodiment method or process are presented and described sequentially, one of ordinary skill in the art will appreciate that some or all of the steps may be executed in different order, may be combined or omitted, and some or all of the steps may be executed in parallel. The steps may be performed actively or passively. The method or process may be repeated or expanded to support multiple components or multiple users within a field environment. Accordingly, the scope should not be considered limited to the specific arrangement of steps shown in a flowchart or diagram.

Unless defined otherwise, all technical and scientific terms used have the same meaning as commonly understood by one of ordinary skill in the art to which these systems, apparatuses, methods, processes and compositions belong.

The singular forms “a,” “an,” and “the” include plural referents, unless the context clearly dictates otherwise. Within a claim, reference to an element in the singular is not intended to mean “one and only one” unless specifically so stated, but rather “one or more.” Unless specifically stated otherwise, the term “some” refers to one or more.

Embodiments of the present disclosure may suitably “comprise”, “consist” or “consist essentially of” the limiting features disclosed, and may be practiced in the absence of a limiting feature not disclosed. As used here and in the appended claims, the words “comprise,” “has,” and “include” and all grammatical variations thereof are each intended to have an open, non-limiting meaning that does not exclude additional elements or steps.

“Optional” and “optionally” means that the subsequently described material, event, or circumstance may or may not be present or occur. The description includes instances where the material, event, or circumstance occurs and instances where it does not occur.

As used, the term “determining” encompasses a wide variety of actions. For example, “determining” may include calculating, computing, processing, deriving, investigating, looking up (for example, looking up in a table, a database or another data structure), and ascertaining. Also, “determining” may include receiving (for example, receiving information) and accessing (for example, accessing data in a memory). Also, “determining” may include resolving, selecting, choosing, and establishing.

When the word “approximately” or “about” are used, this term may mean that there can be a variance in value of up to +10%, of up to 5%, of up to 2%, of up to 1%, of up to 0.5%, of up to 0.1%, or up to 0.01%.

Ranges may be expressed as from about one particular value to about another particular value, inclusive. When such a range is expressed, it is to be understood that another embodiment is from the one particular value to the other particular value, along with all particular values and combinations thereof within the range.

As used, terms such as “first” and “second” are arbitrarily assigned and are merely intended to differentiate between two or more components of a system, an apparatus, or a composition. It is to be understood that the words “first” and “second” serve no other purpose and are not part of the name or description of the component, nor do they necessarily define a relative location or position of the component. Furthermore, it is to be understood that that the mere use of the term “first” and “second” does not require that there be any “third” component, although that possibility is contemplated under the scope of the various embodiments described.

Although only a few example embodiments have been described in detail, those skilled in the art will readily appreciate that many modifications are possible in the example embodiments without materially departing from the disclosed scope as described. Accordingly, all such modifications are intended to be included within the scope of this disclosure as defined in the following claims. In the claims, means-plus-function clauses are intended to cover the structures described as performing the recited function and not only structural equivalents, but also equivalent structures. For example, although a nail and a screw may not be structural equivalents in that a nail employs a cylindrical surface to secure wooden parts together, whereas a screw employs a helical surface, in the environment of fastening wooden parts, a nail and a screw may be equivalent structures. It is the express intention of the applicant not to invoke 35 U.S.C. § 112(f), for any limitations of any of the claims, except for those in which the claim expressly uses the words ‘means for’ together with an associated function.

The following claims are not intended to be limited to the embodiments provided but rather are to be accorded the full scope consistent with the language of the claims.

What is claimed is:

1. An epitaxial growth processing chamber, comprising:
a component having a macrocell support structure with interconnecting physical supports defining pores that are in fluid communication with one another.

2. The epitaxial growth processing chamber of claim 1, wherein the component is a lower liner, an upper liner, a baseplate, an exhaust cap, an injection ring, an injection cap, or combinations thereof.

3. The epitaxial growth processing chamber of claim 1, wherein the interconnecting physical supports comprise a metal, a ceramic or glass material, a polymeric material, or combinations thereof.

4. The epitaxial growth processing chamber of claim 1, wherein the macrocell support structure has a porosity of about 60% to about 99% of a volume of the macrocell support structure.

5. The epitaxial growth processing chamber of claim 1, wherein the pores of the macrocell support structure have an average pore size of about 1 to about 5000 microns.

6. The epitaxial growth processing chamber of claim 1, wherein the macrocell support structure has a permeability of about 20% to about 100% of the pores of the macrocell support structure.

7. The epitaxial growth processing chamber of claim 1, wherein the macrocell support structure is in a free-standing configuration, a plate-supported configuration, a sandwich configuration, an surface sealed configuration, or a solid polymer-filled configuration.

8. The epitaxial growth processing chamber of claim 7, wherein the component is a unitary component.

9. The epitaxial growth processing chamber of claim 7, wherein the macrocell support structure in the sandwich configuration includes a first plate comprising a first material and a second plate comprising a second material, wherein each of the first material and the second material are a similar material to that of the interconnecting physical supports.

10. The epitaxial growth processing chamber of claim 9, wherein the first material and the second material are different.

11. The epitaxial growth processing chamber of claim 7, wherein the macrocell support structure in the surface sealed configuration comprises an encasing surface comprising a different material than the interconnecting physical supports.

12. The epitaxial growth processing chamber of claim 11, wherein the macrocell support structure in the surface sealed configuration further comprises a fluid within the macrocell support structure.

13. A component configured for use in an epitaxial growth processing chamber, comprising:
a macrocell support structure having interconnecting physical supports defining pores that are in fluid communication.

14. The component of claim 13, wherein the component is a lower liner, an upper liner, a baseplate, an exhaust cap, an injection ring, an injection cap, or combinations thereof.

15. The component of claim 13, wherein the interconnecting physical supports comprise a metal, a ceramic or glass material, a polymeric material, or combinations thereof.

16. The component of claim 13, wherein the macrocell support structure has a porosity of about 60% to about 99% of a volume of the macrocell support structure.

17. The component of claim 13, wherein the pores of the macrocell support structure have an average pore size of about 1 to about 5000 microns.

18. The component of claim 13, wherein the macrocell support structure has a permeability of about 20% to about 100% of the pores of the macrocell support structure.

19. A component configured for use in an epitaxial growth processing chamber, comprising:
a macrocell support structure having interconnecting physical supports defining pores that are in fluid communication, wherein the macrocell support structure is in a free-standing configuration, a plate-supported configuration, a sandwich configuration, a surface sealed configuration, or a solid polymer-filled configuration.

20. The component of claim 19, wherein the component is a unitary component.
